(19) United States
(12) Patent Application Publication
(10) Pub. No.: US 2010/0305890 A1
(43) Pub. Date: Dec. 2, 2010

(54) SYSTEM AND METHOD FOR EVALUATING POWER USAGE

(75) Inventor: Hsueh Cheng Huang, Hamilton (NZ)

Correspondence Address: EDWARDS ANGELL PALMER & DODGE LLP, P.O. BOX 55874, BOSTON, MA, 02205, US

(73) Assignee: OPEN MINDER GROUP LIMITED, Tortola (VG)

(21) Appl. No.: 12/730,596

(22) Filed: Mar. 24, 2010

(30) Foreign Application Priority Data
Jun. 1, 2009 (TW) 098117969

(51) Int. Cl. G01R 21/06; G01R 31/36; G06F 19/00; G06Q 10/00

(52) U.S. Cl. 702/62; 702/63; 705/7

(57) ABSTRACT

A system and method for evaluating power usage, applicable to a power consumption environment provided among a power supplying device, a battery, and a power supplying network, are provided. The method includes: receiving, by a receiving module, information about power usage, information about characteristics of the power supplying device, information about characteristics of the battery, and information about characteristics of the power supplying network entered by a user; storing the above-mentioned information to a storing module by the receiving module; and analyzing or comparing the above-mentioned information by an evaluating module according to a preset rule or algorithm so as to calculate information about power consumption. The system and method are effective in analyzing, evaluating and optimizing power consumption behavior of users, thereby assisting users in deciding on the best power consumption mode according to the calculated information about power consumption.

### BACKGROUND OF THE INVENTION

1. Field of the Invention

The present invention relates to systems and methods for evaluating power usage, and more particularly, to a system and method for evaluating power usage applicable to a power supplying device, a battery and a power supplying network.

2. Description of Related Art

Energy drives our modern economies, and electricity is a critical form of energy due to its cleanness, high efficiency and widespread distribution. Lighting, appliances and industrial equipment all utilize electricity, and even some vehicles are powered by electricity. As such, finding new ways to generate electricity, particularly green ways, is becoming more important, such as generating electricity from solar, wind and water, as well as power generation from recycled energy. However, these new and green electricity sources are still not popular and widely used due to various factors, such as unconventional generating equipment or the lack of stability of the electricity supplied from such sources.

As a result, today, most electrical power is generated in generating plants by burning fossil fuels (coal and gas) or by using nuclear power, both of which are used to boil water to produce steam to drive generating turbines. For various reasons, the generating plants are often not located where the electrical energy is consumed, and so the electricity produced must be distributed. High voltage, high tension power lines and towers transfer the electrical energy produced to desired areas, where substations with step-down transformers reduce the voltage and feed the electricity to businesses and households. To keep electrical energy flowing reliably and stably, electrical lines of various areas are interconnected to form a network. Using such a power-distribution network, society enjoys the convenience of electricity. Furthermore, electricity can be stored in a battery for times when electricity is not available or for portable use. The types of batteries can be categorized into primary cells and secondary cells. Primary cells include dry cells, mercury cells and alkaline cells, and secondary cells include lead-acid cells, a nickel-cadmium cells, nickel hydride cells, and lithium-ion cells. In addition, fuel cells that use fuel, such as powered metal, gas or liquid, may also be used to produce and store electricity for later use.

Fossil-fuel and nuclear generation methods provide most of the electricity stored by such batteries. However, it is getting harder to build new power plants to increase power production because the required land is more difficult to acquire due to urban growth, and people are increasingly worried about pollution and radioactivity from conventional and nuclear power plants, respectively. And even the emerging so-called green power technologies cannot solve or satisfy the increasing requirement for electricity in time. Thus, it is more time-efficient to optimize the usage of electricity in terms of efficiency and conservation than to invest in developing power generation.

However, it is difficult for a consumer or user to judge the pros and cons among the various available power supplying devices and batteries. There is too little information readily available to consumers about the power supplying mode of the power supplying network for consumers to choose the most appropriate power consumption mode for their needs, consumption behavior and budget. Moreover, various producers and distributors are often involved in the generation and distribution of electricity, making it especially difficult to provide individual consumers or users with customized, optimal power usage/consumption programs.

Therefore, it has become a critical issue to provide a system and method for evaluating power usage, wherein the system and method are capable of providing a consumer with a customized power consumption mode according to the consumer's consumption behavior.

### SUMMARY OF THE INVENTION

In order to overcome the drawbacks of the prior art, the present invention provides a power usage evaluating system applicable to a power consumption environment provided among a power supplying device, a battery and a power supplying network. The power usage evaluating system comprises: a receiving module configured to receive information about power usage, information about the characteristics of the power supplying device, the battery and the power supplying network entered by a user; a storage module configured to store the entered information about power usage and information about the characteristics of the power supplying device, the battery and the power supplying network; and an evaluating module configured to calculate power consumption information by analyzing and comparing the information about power usage and information about the characteristics of the power supplying device, the battery and the power supplying network stored on the storage module, according to a preset rule or algorithm.

In a preferred embodiment of the present invention, the power usage evaluating system further includes: a display module configured to display power consumption information for the user to let the user appropriately choose a power consumption program or a solution package, and a feedback module configured to generate integrated operating information for an electricity supplier in order to evaluate and optimize cost control, by means of evaluating the power consumption information depending on the preset or entered operating parameters.

The present invention further provides a method for evaluating power that is applicable to a power consumption environment provided among a power supplying device, a battery, and a power supplying network. The method includes the following steps: first, receiving information about power usage and the characteristics of the power supplying device, the battery, and the power supplying network entered by a user; then storing the information about power usage and the characteristics of the power supplying device, the battery, and the power supplying network; finally, calculating the power consumption information by analysing or comparing the stored information about power usage and the characteristics of the power supplying device, the battery, and the power supplying network according to a preset rule or algorithm.

In another preferred embodiment, the method further includes the step of displaying power consumption information for a user to let the user appropriately choose a power consumption program or a solution package. In yet another preferred embodiment, the method further includes the step of generating integrated operating information for an electricity supplier as the bases of evaluating and optimizing cost control, by means of evaluating the power consumption information depending on the preset or entered operating parameters.

When compared with the prior art, the system and method for evaluating power usage of the present invention may optimize a user's power consumption mode by providing the user customized information about power consumption, usage information about the power supplying network and/or package information about electric utility service plans, through analyzing and comparing the user's power usage behavior, environment and other parameters. In addition, the electricity suppliers or venders may also take advantage of the present invention to optimize or improve the control operational costs.

### BRIEF DESCRIPTION OF DRAWINGS

FIG. 1 is a block diagram of the architecture of the power usage evaluating system according to the present invention;

FIG. 2 is a block diagram of another architecture of the power usage evaluating system according to the present invention;

FIG. 3 is a block diagram of the architecture of the power usage evaluating system in application, according to an embodiment of the present invention; and

FIG. 4 is a flow diagram illustrating the method for evaluating power usage according to the present invention.

### DETAILED DESCRIPTION OF PREFERRED EMBODIMENTS

Specific embodiments are herein described in detail to explain the present invention, wherein numerous advantages and effects will become readily apparent to those skilled in the art once the disclosure is fully appreciated. It should be noted that the present invention may be implemented by various embodiments.

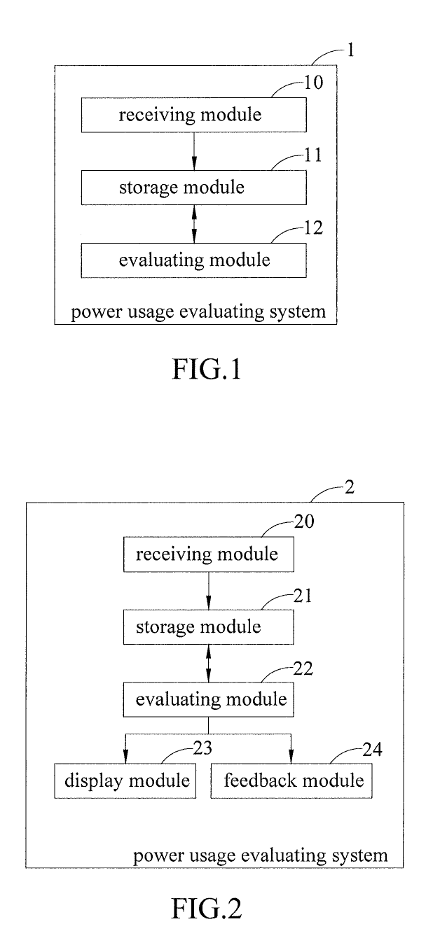

FIG. 1 shows the architecture of the power usage evaluating system according to the present invention. As shown in FIG. 1, the said system is applicable to the power consumption environment (not shown) provided among a power supplying device, a battery and a power supplying network. The power usage evaluating system 1 comprises the components of a receiving module 10, storage module 11, and evaluating module 12.

These individual components are described in detail as follows.

In one embodiment, the receiving module 10 includes a keyboard, a handwriting board, a CD/DVD reader, a sensor, a detector, or other input devices. It is used to receive related reference information, information about power usage, characteristics of a power supplying device, a battery, and a power supplying network entered by a user. In the power usage evaluating system 1, reference information can be entered into the receiving module 10 in advance. The reference information includes information about commercially available power supplying devices, batteries, marketing channels, and current and future electricity prices. Users can browse the web or magazines and manually enter information into the receiving module 10. Alternatively, the power usage evaluating system 1 can update the reference information automatically through the Internet.

Storage module 11 is a database stored on a common storage medium like a hard disk, compact disk, non-volatile memory drive or storage card. It is used to store the information received by the receiving module 10, like reference information, information about power usage, or characteristics of a power supplying device, a battery, and a power supplying network. The evaluating module 12 may be a processing device like a CPU, a remote processor, or a computing center. Using a preset rule or algorithm, it calculates power consumption information by analyzing and comparing the reference information, information about power usage, information about the power supplying device, and the characteristics of the battery and power supplying network.

In a preferred embodiment, the information about power usage includes basic user information, power usage demand information and/or behavior modes of energy consumption. Such information may include, for example, the age, gender, height, weight, power consumption behavior, environment, frequency and/or budget for related electric utility service plans. The power supplying device may include solar panels or solar generators, hydroelectric generators or generator sets, wind power generator sets and/or various kinds of fuel cells. The fuel used can be a kind of metal (e.g. Li, Fe, Ca, Zn, Mg and/or Al), air, hydrogen, methanol, ethanol, natural gas, or even gasoline.

In this preferred embodiment, if the power supplying device is a metal-air fuel cell, the characteristics of the power supplying device further includes the conversion ratio of metal quantity to generated energy output. In addition, if the power supplying device is a fuel cell that consumes hydrogen, methanol, ethanol, natural gas or gasoline, the characteristics of such a power supplying device further includes the conversion ratio of a quantity of these kinds of fuel to generated energy output.

In another preferred embodiment, the battery may be a primary battery, a secondary battery, or a composite battery comprising a primary battery, a secondary battery and/or various kinds of fuel cells. The primary battery may be a common dry cell battery, a mercury cell or an alkaline battery; and the secondary battery may be a lead-acid battery, a nickel-cadmium cell, a nickel hydride battery, a lithium-ion cell, a lithium polymer cell, and so on. As for the characteristics of the battery, they may include weight, size, volume, price, minimum time to be fully charged, maximum service time, venders or retailers, and suggested safe lifetime.

In another preferred embodiment, the power supplying network may be a power system network provided by common power companies, or it can be a charging station or battery replacement station. For example, the power supplying network may be one that transfers electricity from power plants, like conventional or nuclear power plants, to a metropolis, wherein the high voltage used during long-distance distribution is further transformed into the household voltage. The characteristics of the power supplying network includes power rate, power mode, service time and/or power capacity. In addition, the information about the power supplying network also includes schedules of discount hours offered by a power company.

In yet another preferred embodiment, the power consumption information may include recommended information about the power supplying device; recommended information about battery types; recommended information about battery ratio; battery maintenance, battery volume, or battery usage; usage information about the power supplying network; and/or package information about electric utility service plans.

For example, a user would like to use a composite battery comprising a primary battery and a secondary battery. Through the disclosed power usage evaluating system 1, the user can evaluate the most appropriate type of a battery, mode of a power supplying network and mode of power usage, as well as information related to the maintenance and suitable charging methods for that battery.

Take a metal-air fuel cell as an example. The metal-air fuel cell is a power supplying device. Consumers who use a metal-air fuel cell can ascertain the best mode of power consumption through the power usage evaluating system, according to the present invention. The best mode of power consumption includes recommended information about metal types, package information about metal consumption (e.g. paid in an annual base), information about metal reserves and/or recycling information about metal oxides (waste of a fuel cell). If the power usage evaluating system 1 recommends to a consumer to use a hydrogen fuel cell, the power consumption information may include package information about hydrogen consumption, information about hydrogen reserve and/or recycling information for the products of reaction of the hydrogen fuel cell (i.e. water).

For example, a user would like to choose a composite battery for his vehicle. Through the power usage evaluating system 1, she can estimate the best mode of power consumption. For example, assume that this user is a woman in her sixties and lives in the suburbs. Everyday it takes two hours for her to drive to work at an average speed of 60 km/hr. According to the said information about power usage, the power usage evaluating system 1 issues a recommendation for her to choose a composite battery, which consists of a conventional battery and a metal-air fuel cell in a ratio of 60% to 40%. Each day, the user can charge the conventional battery part (60% of the composite battery) from the power supplying network in her house, which is sufficient for her general use. The other part of the 40% metal-air fuel cell is then sufficient for her to drive for a longer time and distance.

In another embodiment, the metal-air fuel cell is an Al-air one. Although the price of Al is usually higher, it is more applicable to longer distances or where highly efficient transportation is needed (such as the case of a taxi), as well as highway transportation because Al has less weight and a higher energy density. In addition, the recommended information from the power usage evaluating system 1 may be in the form of packaged electric utility service plans. It is apparent that the power consumption information evaluated by the power usage evaluating system 1 can also suggest various power supplying device, a variety of batteries and their combinations, and an index of suitability for a certain user.

In addition, when the fuel of a fuel cell is running out, users can also be informed to recycle the waste (metal oxides) to a recycling station and to get a reward. If the fuel cell is a metal fuel cell, of which the waste is hydrogen, users will be informed to recycle the hydrogen to the recycle station. Then, the hydrogen waste will be collected in a storage system and be sold to those who need hydrogen as fuel. Thereby, a bidirectional system of with mutual interest is formed, the risk of transporting hydrogen is lowered, and the cost of hydrogen mass production and transportation is also distributed. The applied technologies about hydrogen are well known to those with ordinary skill in the art and will not be mentioned here for brevity.

In another preferred embodiment, the power usage evaluating system 1 may be implemented by computer software. For example, the power usage evaluating system 1 may be a computer program or software stored on a personal computer, a notebook, a PDA or a network server.

FIG. 2 shows another exemplary architecture of the power usage evaluating system according to the present invention. The power usage evaluating system 2 of the present invention is applicable to a power consumption environment (not shown) provided among a power supplying device, a battery and a power supplying network. The power evaluation system 2 comprises a receiving module 20, storage module 21, evaluating module 22, display module 23 and feedback module 24.

These individual components are described in detail as follows.

When the system is operating, the receiving module 20 receives related reference information, information about power usage, and the characteristics of the power supplying device, the battery and the power supplying network entered by a user. Then, the storage module 21 stores the reference information, the information about power usage, and the characteristics of the power supplying device, the battery and the power supplying network. Further, the evaluating module 22 calculates power consumption information by analyzing or comparing the information about power usage, and the characteristics of the power supplying device, the battery, and the power supplying network stored on the storage module 21, according to a preset rule or algorithm.

Compared with the architecture in FIG. 1, this embodiment has two additional modules: display module 23 and feedback module 24. The display module 23 is configured to display the power consumption information for the user to determine an optimal power consumption program. It may be a PC monitor, a laptop computer monitor, a touch screen or another common display. The feedback module 24 may be a general device or system capable of learning, gathering statistics, analyzing and processing, such as an artificial intelligent (AI) system or a neural network processing system. It is configured to generate integrated operating information for an electricity supplier in order to evaluate and optimize cost control, by means of evaluating the power consumption information depending on the preset or entered operating parameters.

It should be noted that power usage evaluating system 2 of the present invention may be implemented by a computer software program. The system 2 can be stored on a PC, a laptop computer, a PDA or a network server; that is, it is not required to be implemented by a separate physical device comprising electronic circuits.

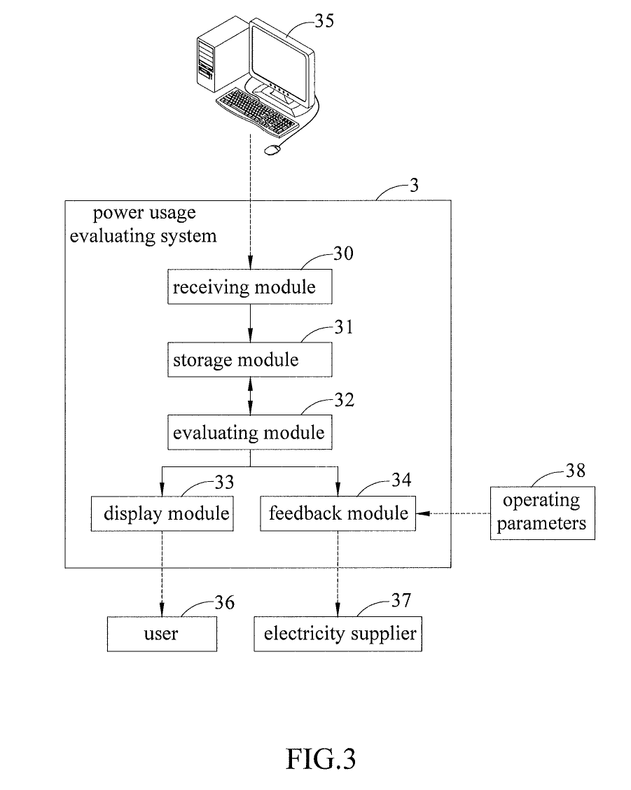

FIG. 3 shows the architecture of the power usage evaluating system in application according to an embodiment of the present invention. The power usage evaluating system 3 comprises a receiving module 30, storage module 31, evaluating module 32, display module 33, and feedback module 34.

These individual components are described in detail as follows.

In a preferred embodiment, a user first enters information about power usage, and the characteristics of a power supplying device, a battery and a power supplying network to the receiving module 30 with personal computer 35. Then the receiving module 30 transfers the information about power usage, and the characteristics of a power supplying device, a battery and a power supplying network to the storage module 31 where such information is stored. In this embodiment, the storage module 31 has reference information stored in advance. The evaluating module 32 calculates the power consumption information by analyzing and comparing the information about power usage, and the characteristics of the power supplying device, the battery, and the power supplying network on the storage module 31, according to the reference information.

Furthermore, the display module 33 is configured to display the power consumption information for the user 36 to determine a power consumption program. The feedback module 34 is configured to generate integrated operating information for an electricity supplier 37 in order to evaluate and optimize cost control, by means of evaluating the power consumption information depending on the preset or entered operating parameters 38. The operating parameters 38 include the market price of raw material futures, raw material costs, raw material capacity, and so on, such as common financial information like capacity or the future market price of a metal, hydrogen, methanol, ethanol, natural gas or gasoline. The integrated operating information (not shown) includes information about futures, the cost and capacity of raw materials, information about operational risks, and so on. Thus, according to the integrated operating information evaluated by the feedback module 34, the electricity supplier 37 can further verify cost control (e.g. stock) and the results of such cost verification can be used as the reference base by the electricity supplier 37 for future purchases, thereby achieving the goal of optimizing operational flow and/or cost control for the electricity supplier 37.

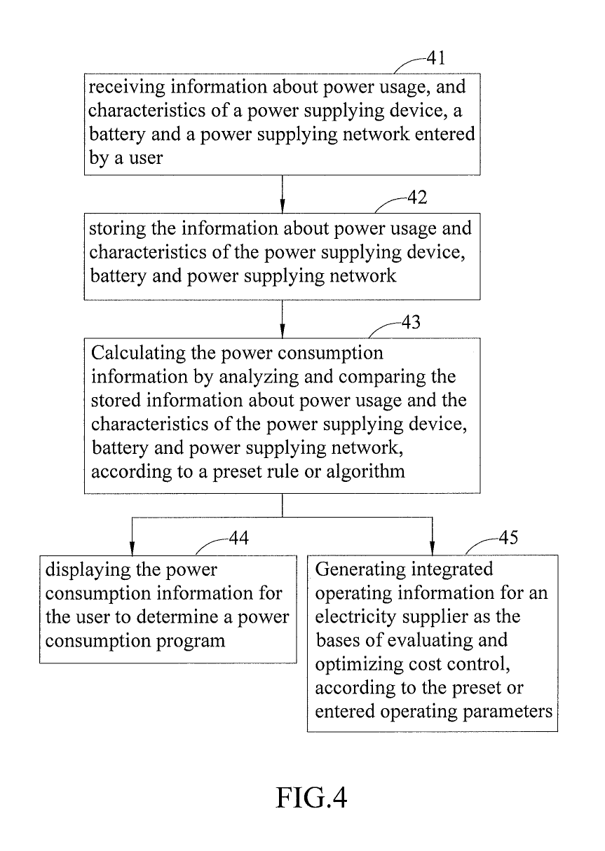

FIG. 4 is a flow diagram illustrating the method for evaluating power usage according to the present invention. The method for evaluating power usage is applicable to the power consumption environment provided among a power supplying device, a battery and a power supplying network. The method for evaluating power includes the following steps:

In Step S41, information about power usage entered by a user is received, as well as characteristics of a power supplying device, a battery and a power supplying network. The information about power usage includes basic user information, power usage demand information and/or behavior modes of energy consumption, such as age, gender, power consumption behavior, environment, frequency or budget, and so on. The power supplying device may include, but is not limited to, solar panels, hydroelectric generator sets, wind power generator sets and/or fuel cells. The battery may be a primary battery and/or a secondary one. The characteristics of the battery include price, charging/discharging time, lifetime, weight and/or size. The characteristics of the power supplying network includes power rate, power mode, service time and/or power capacity. If the fuel cell is a metal-air fuel cell, the characteristics of the metal-air fuel cell further include the conversion ratio of metal quantity to generated energy output. If the fuel cell is a hydrogen fuel cell, the characteristics of the hydrogen fuel cell further include the conversion ratio of hydrogen volume to generated energy output. Next, proceed to Step S42.

In Step S42, the information about power usage is stored, as well as the characteristics of the power supplying device, battery and power supplying network. Such information is stored in a database on, for example, a hard disk, a flash disk, or other storage devices. Next, proceed to Step S43.

In Step S43, the power consumption information is calculated by analyzing and comparing the stored information about power usage and the characteristics of the power supplying device, battery and power supplying network, according to a preset rule or algorithm. The power consumption information includes recommended information about the power supplying device; recommended information about battery types; recommended information about battery ratio, battery maintenance, battery volume, and battery usage; and usage information about the power supplying network and/or package information about electric utility service plans. Next, proceed to Step S44 or S45.

In Step S44, the power consumption information is displayed for the user to determine a power consumption program.

In Step S45, the integrated operating information is generated for an electricity supplier in order to evaluate and optimize its cost control, according to the preset or entered operating parameters.

In a preferred embodiment, reference information may be stored in advance in Step S42. In Step S43, the power consumption information can be calculated by comparing the information about power usage and the characteristics of the power supplying device, the battery and the power supplying network, according to the reference information.

In conclusion, based on the system and method for evaluating power according to the present invention, the information about power consumption customized for a certain user, the usage information about the power supplying network, and/or package information about electric utility service plans (e.g., an annually contracted package), is generated by analyzing and comparing the user's power usage behavior, the power usage environment and other parameters and information. On the one hand, the user (a consumer or a system user) can understand and execute the optimized power consumption mode. On the other hand, the manufacturers, electricity (battery) venders, or electricity (battery) suppliers can also take advantage of the present invention to generate integrated operating information as the bases of evaluating and optimizing cost control, by means of evaluating the power consumption information depending on the preset or entered operating parameters.

1. A system for evaluating power usage applicable to power consumption environment including at least a power supplying device, a battery and a power supplying network, comprising:
a receiving module configured to receive information about power usage, information about characteristics of the power supplying device, information about characteristics of the battery, and information about characteristics of the power supplying network entered by a user;
a storage module configured to store the information about power usage, the information about characteristics of the power supplying device, the information about characteristics of the battery, and the information about characteristics of the power supplying network; and
an evaluating module configured to calculate power consumption information by analyzing or comparing the information about power usage, the information about characteristics of the power supplying device, the information about characteristics of the battery, and the information about characteristics of the power supplying network stored on the storage module, according to a preset rule or algorithm.

2. The system of claim 1, wherein the storage module is configured to store reference information in advance, so as for the evaluating module to calculate the power consumption information by comparing and analyzing the information about power usage, the information about characteristics of the power supplying device, the information about characteristics of the battery, and the information about characteristics of the power supplying network stored on the storage module according to the reference information, and wherein the reference information includes information about vendors' stock and/or marketing channel for the power supplying device or the battery.

3. The system of claim 1, further comprising a display module configured to display the power consumption information for the user to choose a power consumption program or a solution package.

4. The system of claim 1, further comprising a feedback module configured to generate integrated operating information for an electricity supplier in order to evaluate and optimize cost control, by means of evaluating the power consumption information depending on preset or entered operating parameters.

5. The system of claim 1, wherein the information about power usage includes basic user information, power usage demand information, environmental information and/or behavior modes of energy consumption, the information about characteristics of the battery includes price, charging/discharging time, lifetime, weight and/or size, the information about characteristics of the power supplying network includes power rate, power mode, service time and/or power capacity, and the power consumption information includes recommended information about the power supplying device, recommended information about battery types, recommended information about battery ratio, battery maintenance, battery capacity, and battery usage, and usage information about the power supplying network and/or package information about electric utility service plans.

6. The system of claim 1, wherein the power supplying device is one selected from the group consisting of solar panels, hydroelectric generator sets, wind power generator sets and fuel cells, and wherein the battery is a primary battery and/or a secondary battery.

7. The system of claim 6, wherein the fuel cell is a metal-air fuel cell, and metal used in the metal-air fuel cell is one selected from the group consisting of Li, Fe, Ca, Zn, Mg and Al.

8. The system of claim 7, wherein the information about characteristics of the metal-air fuel cell includes conversion ratio of metal quantity to generated energy output, and the power consumption information includes recommended information about metal types, package information about metal consumption, information about metal reserves and/or recycling information about metal oxides.

9. The system of claim 6, wherein the fuel cell is a hydrogen fuel cell.

10. The system of claim 9, wherein the information about characteristics of the hydrogen fuel cell includes the conversion ratio of hydrogen volume to generated energy output, and the power consumption information includes package information about hydrogen consumption, information about hydrogen reserve and/or recycling information from the reaction occurring in the hydrogen fuel cell.

11. The system of claim 1, which is implemented by computer software, and the computer software is stored on a storage medium.

12. A method for evaluating power usage applicable to a power consumption environment including a power supplying device, a battery and a power supplying network, comprising the steps of:
(1) receiving information about power usage, information about characteristics of the power supplying device, information about characteristics of the battery, and information about characteristics of the power supplying network entered by a user;
(2) storing the information about power usage, the information about characteristics of the power supplying device, the information about characteristics of the battery, and the information about characteristics of the power supplying network; and
(3) calculating power consumption information by analyzing or comparing the information about power usage, the information about characteristics of the power supplying device, the information about characteristics of the battery, and the information about characteristics of the power supplying network stored in the Step (2), according to a preset rule or algorithm.

13. The method of claim 12, wherein Step (2) further comprises storing reference information in advance, and Step (3) further comprises calculating the power consumption information by analyzing and comparing the information about power usage, the information about characteristics of the power supplying device, the information about characteristics of the battery, and the information about characteristics of the power supplying network, according to the reference information, and wherein the reference information includes information about vendors' stock and/or marketing channels for the power supplying device or the battery.

14. The method of claim 12, further comprising:
(4) displaying the power consumption information for the user to determine a power consumption program.

15. The method of claim 12, further comprising:
(4) generating integrated operating information for an electricity supplier in order to evaluate and optimize cost control, by means of evaluating the power consumption information depending on preset or entered operating parameters.

16. The method of claim 12, wherein the information about power usage includes basic user information, power usage demand information, environmental information and/or behavior modes of energy consumption, the information about characteristics of the battery includes price, charging/discharging time, lifetime, weight and/or size, the information about characteristics of the power supplying network includes power rate, power mode, service time and/or power capacity, and the power consumption information includes recommended information about the power supplying device, recommended information about battery types, recommended information about battery ratio, battery maintenance, battery capacity, and battery usage, and usage information about the power supplying network and/or package information about electric utility service plans.

17. The method of claim 12, wherein the power supplying device is one selected from the group consisting of solar panels, hydroelectric generator sets, wind power generator sets and/or fuel cells, and the battery is a primary battery and a secondary batter.

18. The method of claim 17, wherein the fuel cell is a metal-air fuel cell, and metal used in the metal-air fuel cell is one selected from the group consisting of Li, Fe, Ca, Zn, Mg and/or Al.

19. The method of claim 18, wherein the information about characteristics of the metal-air fuel cell includes conversion ratio of metal quantity to generated energy output, and the power consumption information includes recommended information about metal types, package information about metal consumption, information about metal reserves and/or recycling information about metal oxides.

20. The method of claim 17, wherein the fuel cell is a hydrogen fuel cell, the information about characteristics of the hydrogen fuel cell includes conversion ratio of hydrogen volume to generated energy, and the power consumption information includes package information about hydrogen consumption, information about hydrogen reserves and/or recycling information from the reaction occurring in the hydrogen fuel cell.
